(19) United States
(12) Patent Application Publication
(10) Pub. No.: US 2015/0263717 A1
(43) Pub. Date: Sep. 17, 2015

(54) VOLTAGE MONITORING CIRCUIT AND SEMICONDUCTOR INTEGRATED CIRCUIT

(71) Applicant: Kabushiki Kaisha Toshiba, Tokyo (JP)

(72) Inventor: Yoshihide Nakajima, Yokohama (JP)

(73) Assignee: KABUSHIKI KAISHA TOSHIBA, Minato-ku, Tokyo (JP)

(21) Appl. No.: 14/482,740

(22) Filed: Sep. 10, 2014

(30) Foreign Application Priority Data
Mar. 13, 2014 (JP) 2014-050862

(51) Int. Cl. H03K 5/24

(52) U.S. Cl. CPC H03K 5/2481

(57) ABSTRACT

A controlling circuit of the voltage monitoring circuit turns on a first positive-side switch and a first negative-side switch, turns off a second positive-side switch and a second negative-side switch, and sets a switch circuit in a first connection state, and after that, the controlling circuit turns off the first positive-side switch and the first negative-side switch, and after that, the controlling circuit sets the switch circuit in a second connection state.

### CROSS-REFERENCE TO RELATED APPLICATION

This application is based upon and claims the benefit of priority from the prior Japanese Patent Application No. 2014-050862, filed on Mar. 13, 2014, the entire contents of which are incorporated herein by reference.

### BACKGROUND

1. Field

Embodiments described herein relate generally to a voltage monitoring circuit and a semiconductor integrated circuit.

2. Background Art

A flash memory, for example, requires a plurality of boosting circuits that generate a high voltage for writing and erasing of data.

A conventional flash memory has a dedicated pad for a voltage measuring monitor in order to check whether or not the boosted voltage from the plurality of boosting circuits is properly output.

The dedicated pad is designed for analog voltage measurement and cannot be used with a digital pad. In addition, the flash memory requires a further dedicated pad for a voltage measuring monitor for negative potential. Thus, the flash memory has an increased number of pads.

Furthermore, with the configuration described above, pads of the product package are less likely to include the pad dedicated for the voltage measuring monitor, and it is difficult to measure the internal voltage by analysis or the like.

### BRIEF DESCRIPTION OF THE DRAWINGS

FIG. 1 is a circuit diagram showing an example of a configuration of a semiconductor integrated circuit 1000 according to a first embodiment;

FIG. 2 is a diagram showing an example of interconnections in the semiconductor integrated circuit 1000 in a case where the switch circuit “SWC” in FIG. 1 is in the first connection state;

FIG. 3 is a diagram showing an example of a state where the switch circuit “SWC” in FIG. 1 is in the second connection state;

FIG. 4 is a diagram showing an example of a state where the reset switch “SWX” in the output circuit 101 is turned on after the switch circuit “SWC” in the voltage monitoring circuit 100 is once in the first connection state;

FIG. 5 is a diagram showing an example of a state where the output circuit 101 in FIG. 1 outputs the monitoring signal “SOUT” responsive to the potential difference between the first output node “Na” and the second output node “Nb”;

FIG. 6 is a waveform diagram showing an example of waveforms of signals in the voltage monitoring circuit 100 in a case where the voltage monitoring circuit 100 monitors the first positive voltage output from the first charge pump “VCP1”;

FIG. 7 is a waveform diagram showing an example of signal waveforms in the voltage monitoring circuit 100 in the case where the second positive voltage output from the second charge pump “VCP2” is monitored;

FIG. 8 is a diagram showing another example of the interconnections in the semiconductor integrated circuit 1000 in the case where the switch circuit “SWC” in FIG. 1 is in the first connection state;

FIG. 9 is a diagram showing another example of the state where the switch circuit “SWC” in FIG. 1 is in the second connection state;

FIG. 10 is a diagram showing another example of the state where the reset switch “SWX” in the output circuit 101 is turned on after the switch circuit “SWC” in the voltage monitoring circuit 100 is once in the first connection state; and

FIG. 11 is a diagram showing another example of the state where the output circuit 101 in FIG. 1 outputs the monitoring signal “SOUT” responsive to the potential difference between the first output node “Na” and the second output node “Nb”.

### DETAILED DESCRIPTION

A voltage monitoring circuit according to an embodiment is a voltage monitoring circuit that outputs a monitor signal. The voltage monitoring circuit includes a first smoothing capacitor connected between a first positive-side node and a first negative-side node. The voltage monitoring circuit includes a first positive-side switch connected between a first detection node and the first positive-side node. The voltage monitoring circuit includes a first negative-side switch connected between a second detection node and the first negative-side node. The voltage monitoring circuit includes a plurality of monitoring capacitors disposed the first detection node and the second detection node. The voltage monitoring circuit includes a switch circuit being capable of switching between a first connection state and a second connection state, and in the first connection state, the monitoring capacitors being electrically connected in series with each other between the first detection node and the second detection node, and in the second connection state, the monitoring capacitors being electrically connected in parallel with each other between a first output node and a second output node. The voltage monitoring circuit includes an output circuit that outputs the monitoring signal according to the potential difference between the first output node and the second output node. The voltage monitoring circuit includes a controlling circuit that controls the first positive-side switch, the first negative-side switch and the switch circuit.

In the following, an embodiment will be described with reference to the drawings.

### First Embodiment

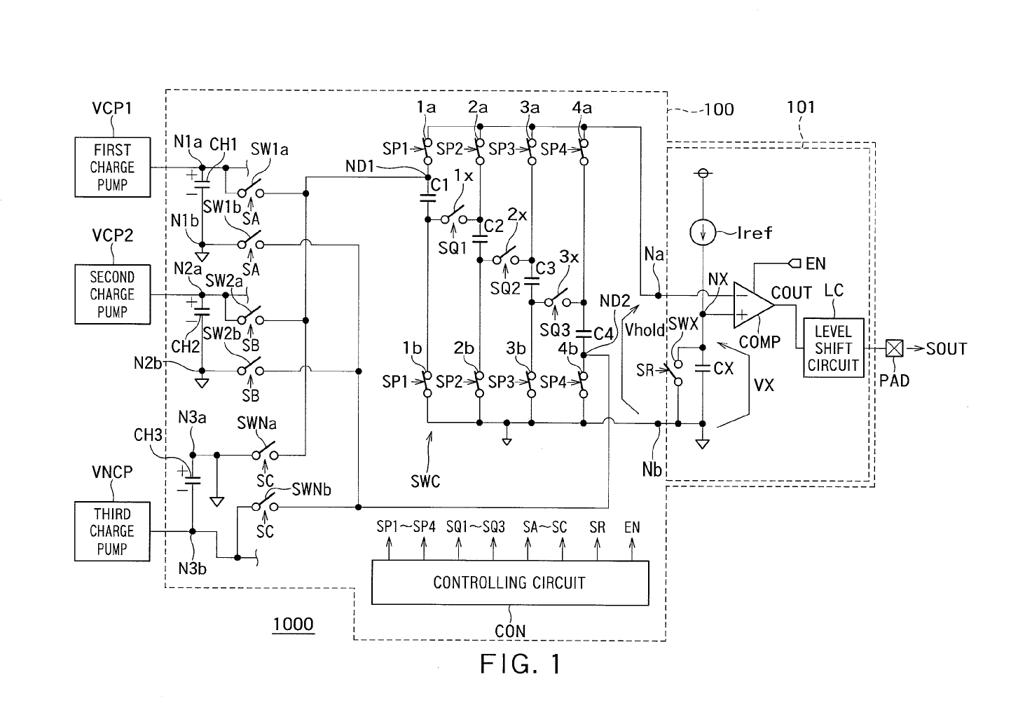

FIG. 1 is a circuit diagram showing an example of a configuration of a semiconductor integrated circuit 1000 according to a first embodiment.

As shown in FIG. 1, the semiconductor integrated circuit 1000 includes a first charge pump “VCP1”, a second charge pump “VCP2”, a third charge pump “VNCP”, a voltage monitoring circuit 100 and a pad electrode “PAD”.

The voltage monitoring circuit 100 monitors a plurality of voltages and outputs a monitor signals “SOUT” that is based on the result of the monitoring to the pad electrode “PAD”.

As shown in FIG. 1, the voltage monitoring circuit 100 includes a first smoothing capacitor “CH1”, a second smoothing capacitor “CH2”, a third smoothing capacitor “CH3”, a first positive-side switch “SW1a”, a first negative-side switch “SW1b”, a second positive-side switch “SW2a”, a second negative-side switch “SW2b”, a third positive-side switch “SWNa”, a third negative-side switch “SWNb”, a plurality of (first to fourth) monitoring capacitors “C1”, “C2”, “C3” and “C4”, a switch circuit “SWC”, an output circuit 101 and a controlling circuit “CON”, for example. Although four monitoring capacitors are shown in the example in FIG. 1, the number of monitoring capacitors can be any number equal to or greater than 2.

The first smoothing capacitor “CH1” is connected between a first positive-side node “N1a”, to which a first positive voltage is supplied, and a first negative-side node “N1b”, which is connected to a fixed potential. The first positive-side node “N1a” is connected to an output of the first charge pump “VCP1” that outputs the first positive voltage. In this example, for example, the fixed potential is a ground potential as shown in FIG. 1 (this holds true for the following description).

The first positive-side switch “SW1a” is connected between a first detection node “ND1” and the first positive-side node “N1a”.

The first negative-side switch “SW1b” is connected between a second detection node “ND2” and the first negative-side node “N1b”.

The second smoothing capacitor “CH2” is connected between a second positive-side node “N2a”, to which a second positive voltage is supplied, and a second negative-side node “N2b”, which is connected to the fixed potential.

The second positive-side switch “SW2a” is connected between the first detection node “ND1” and the second positive-side node “N2a”.

The second negative-side switch “SW2b” is connected between the second detection node “ND2” and the second negative-side node “N2b”.

The third smoothing capacitor “CH3” is connected between a third positive-side node “N3a”, which is connected to the fixed potential, and a third negative-side node “N3b”, to which a negative voltage is supplied.

The third positive-side switch “SWNa” is connected between the first detection node “ND1” and the third positive-side node “N3a”.

The third negative-side switch “SWNb” is connected between the second detection node “ND2” and the third negative-side node “N3b”.

As shown in FIG. 1, the switch circuit “SWC” includes a first upper switch “1a”, a second upper switch “2a”, a third upper switch “3a”, a fourth upper switch “4a”, a first lower switch “1b”, a second lower switch “2b”, a third lower switch “3b”, a fourth lower switch “4b”, a first connection switch “1x”, a second connection switch “2x” and a third connection switch “3x”.

The first upper switch “1a” is connected to a first output node “Na” at one end thereof and to the first detection node “ND1” at another end thereof.

The first monitoring capacitor “C1” is connected to the another end of the first upper switch “1a” at one end thereof. The first lower switch “1b” is connected to another end of the first monitoring capacitor “C1” at one end thereof and to a second output node “Nb” at another end thereof. The second output node “Nb” is connected to the fixed potential (the ground potential).

The second upper switch “2a” is connected to the first output node “Na” at one end thereof.

The second monitoring capacitor “C2” is connected to another end of the second upper switch “2a” at one end thereof.

The second lower switch “2b” is connected to another end of the second monitoring capacitor “C2” at one end thereof and to the second output node “Nb” at another end thereof.

The first connection switch “1x” is connected between the another end of the first monitoring capacitor “C1” and the one end of the second monitoring capacitor “C2”.

The third upper switch “3a” is connected to the first output node “Na” at one end thereof.

The third monitoring capacitor “C3” is connected to another end of the third upper switch “3a” at one end thereof.

The third lower switch “3b” is connected to another end of the second monitoring capacitor “C2” at one end thereof and to the second output node “Nb” at another end thereof.

The second connection switch “2x” is connected between the another end of the second monitoring capacitor “C2” and the one end of the third monitoring capacitor “C3”.

The fourth upper switch “4a” is connected to the first output node “Na” at one end thereof.

The fourth monitoring capacitor “C4” is connected to another end of the fourth upper switch “4a” at one end thereof and to the second detection node “ND2” at another end thereof.

The fourth lower switch “4b” is connected to the another end of the fourth monitoring capacitor “C4” at one end thereof and to the second output node “Nb” at another end thereof.

The third connection switch “3x” is connected between the another end of the third monitoring capacitor “C3” and the one end of the fourth monitoring capacitor “C4”.

The switch circuit “SWC” having the configuration described above is capable of switching between a first connection state, in which any of the first to fourth monitoring capacitors “C1”, “C2”, “C3” and “C4” are electrically connected in series with each other between the first detection node “ND1” and the second detection node “ND2”, and a second connection state, in which any of the first to fourth monitoring capacitors “C1”, “C2”, “C3” and “C4” are electrically connected in parallel with each other between the first output node “Na” and the second output node “Nb”.

In the first connection state, for example, all of the plurality of monitoring capacitors “C1”, “C2”, “C3” and “C4” are electrically connected in series with each other between the first detection node “ND1” and the second detection node “ND2”.

Alternatively, in the first connection state, for example, only two of the plurality of monitoring capacitors “C1”, “C2”, “C3” and “C4”, such as the first monitoring capacitor “C1” and the second monitoring capacitor “C2”, may be electrically connected in series with each other between the first detection node “ND1” and the second detection node “ND2”. That is, the number of monitoring capacitors connected in series with each other can be appropriately adjusted.

In the second connection state, for example, all of the plurality of monitoring capacitors “C1”, “C2”, “C3” and “C4” are electrically connected in parallel with each other between the first output node “Na” and the second output node “Nb”.

Alternatively, in the second connection state, for example, only two of the plurality of monitoring capacitors “C1”, “C2”, “C3” and “C4”, such as the first monitoring capacitor “C1” and the second monitoring capacitor “C2”, may be electrically connected in parallel with each other between the first output node “Na” and the second output node “Nb”. That is, the number of monitoring capacitors connected in parallel with each other can be appropriately adjusted.

The output circuit 101 outputs the monitoring signal “SOUT” to the pad electrode “PAD” according to the potential difference between the first output node “Na” and the second output node “Nb”.

As shown in FIG. 1, the output circuit 101 includes a constant current source “Iref”, an output capacitor “CX”, a reset switch “SWX”, a comparator “COMP” and a level shift circuit “LC”, for example.

The constant current source “Iref” is connected to a power supply at one end thereof and to a reference node “NX” at another end thereof and outputs a constant current.

The output capacitor “CX” is connected to the reference node “NX” at one end thereof and to the second output node “Nb” at another end thereof.

The reset switch “SWX” is connected in parallel with the output capacitor “CX” between the reference node “NX” and the second output node “Nb”. The reset switch “SWX” is turned on and off under the control of the controlling circuit “CON”.

The comparator “COMP” is driven in response to an enable signal “EN” and outputs a comparison result signal “COUT” that is based on the result of comparison between a signal at the first output node “Na” and a signal at a reference node “NX”.

The level shift circuit “LC” shapes the waveform of, and shifts the signal level of, the comparison result signal “COUT” and outputs the resulting signal to the pad electrode “PAD” as the monitoring signal “SOUT”.

As described above, the output circuit 101 generates the comparison result signal “COUT” that is based on the result of comparison between the signal at the first output node “Na” and the signal at the reference node “NX” and outputs the monitoring signal “SOUT” responsive to the comparison result signal “COUT”.

The controlling circuit “CON” controls the first positive-side switch “SW1a”, the second positive-side switch “SW2a”, the first negative-side switch “SW1b”, the second negative-side switch “SW2b”, the third positive-side switch “SWNa”, the third negative-side switch “SWNb”, a reset switch “SR” and the switch circuit “SWC” with control signals “SP1” to “SP4”, “SQ1” to “SQ3”, “SA” to “SC” and “SR”. In addition the controlling circuit “CON” drives the comparator “COMP” with the enable signal “EN”.

Next, an example of an operation of the voltage monitoring circuit 100 having the configuration and functionality described above will be described.

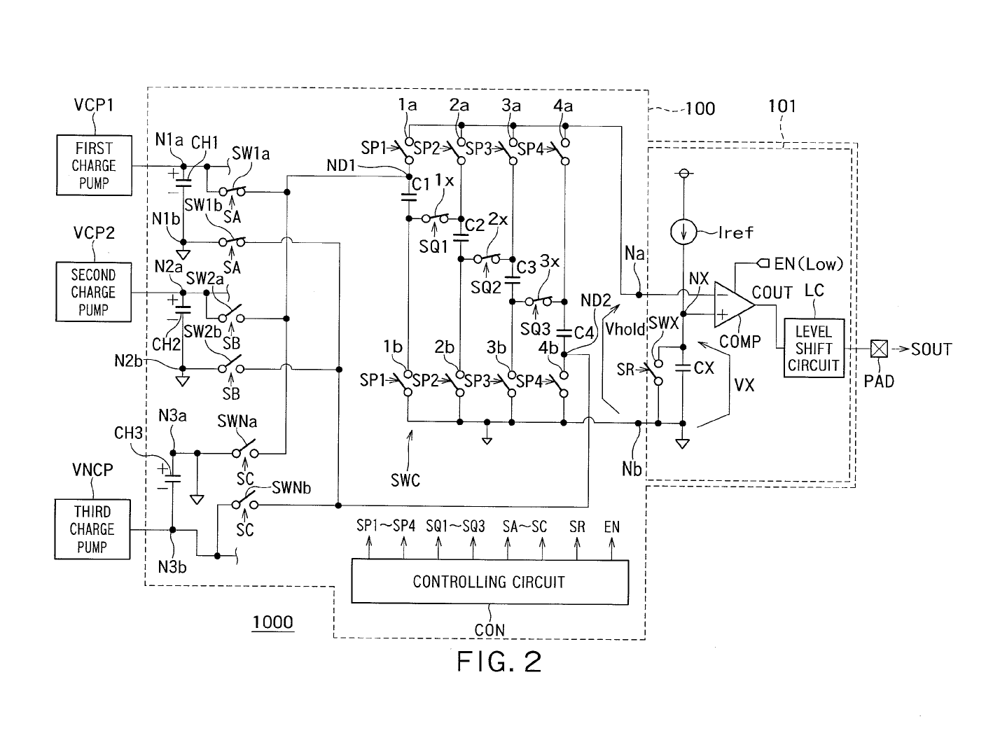

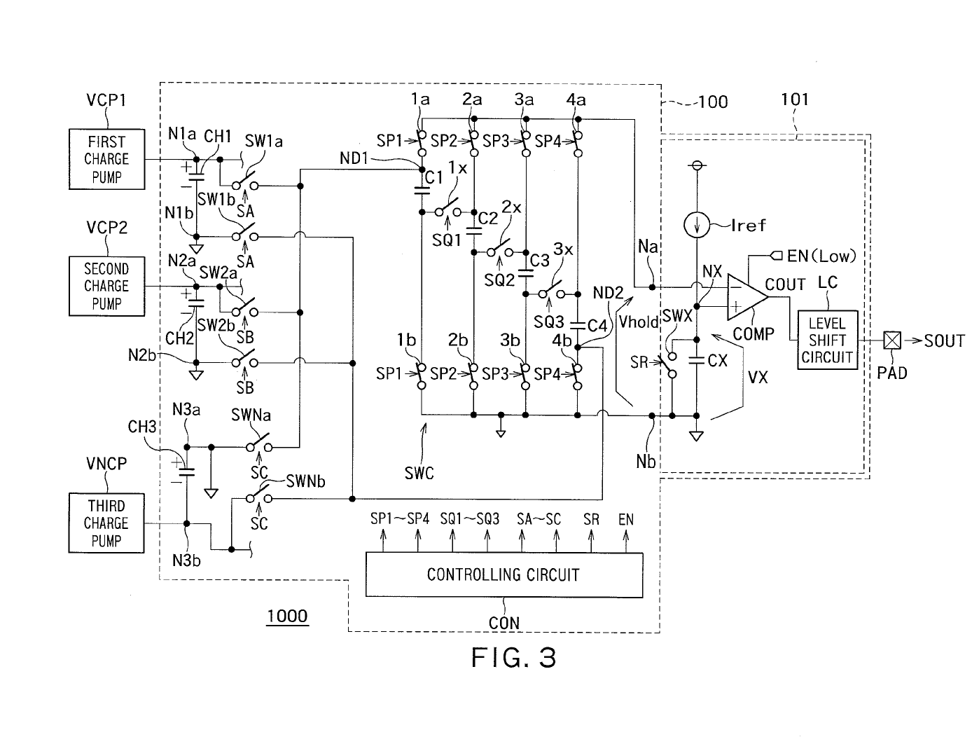

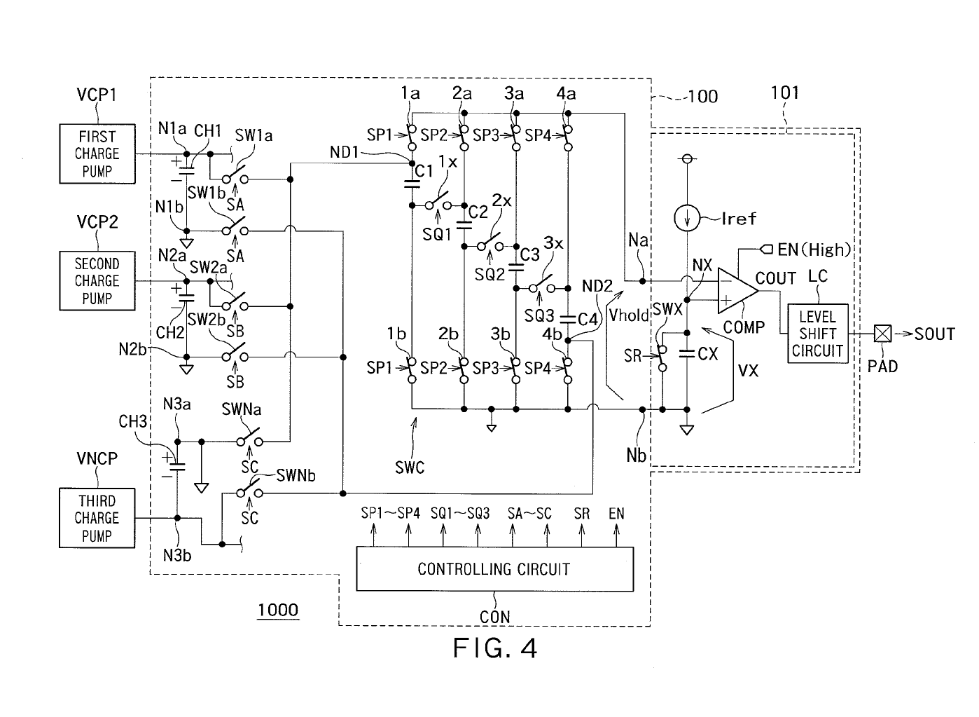

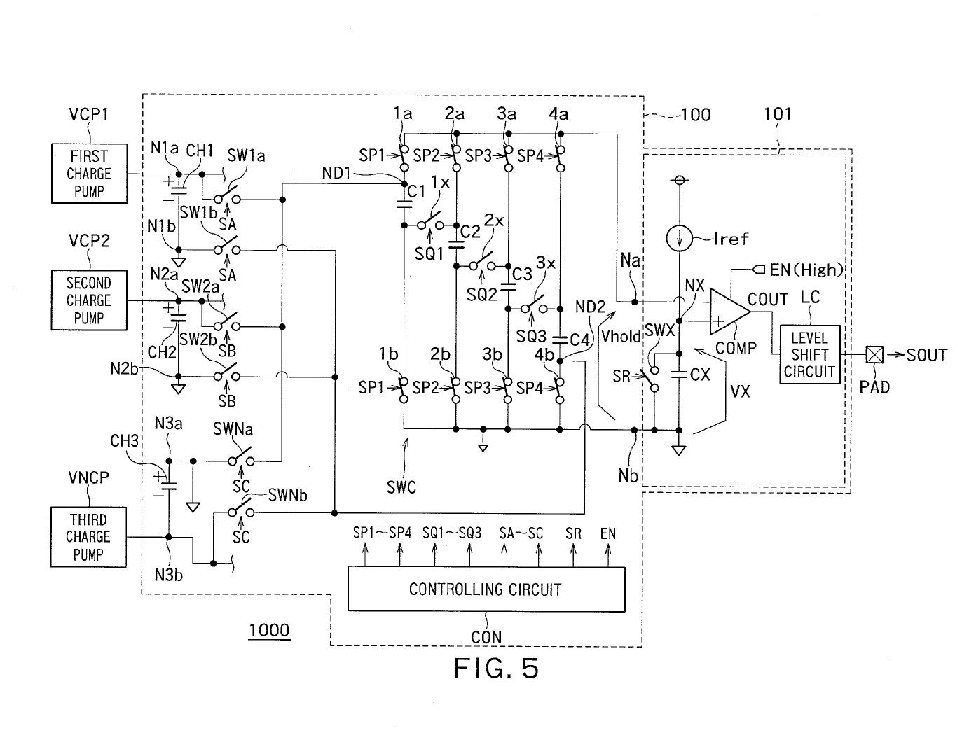

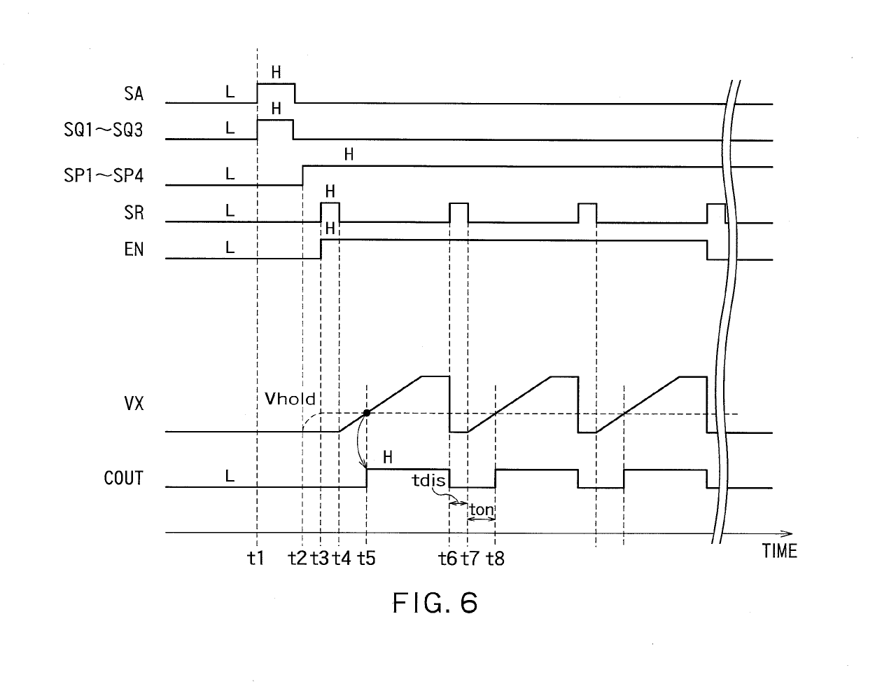

FIG. 2 is a diagram showing an example of interconnections in the semiconductor integrated circuit 1000 in a case where the switch circuit “SWC” in FIG. 1 is in the first connection state. FIG. 3 is a diagram showing an example of a state where the switch circuit “SWC” in FIG. 1 is in the second connection state. FIG. 4 is a diagram showing an example of a state where the reset switch “SWX” in the output circuit 101 is turned on after the switch circuit “SWC” in the voltage monitoring circuit 100 is once in the first connection state. FIG. 5 is a diagram showing an example of a state where the output circuit 101 in FIG. 1 outputs the monitoring signal “SOUT” responsive to the potential difference between the first output node “Na” and the second output node “Nb”. FIG. 6 is a waveform diagram showing an example of waveforms of signals in the voltage monitoring circuit 100 in a case where the voltage monitoring circuit 100 monitors the first positive voltage output from the first charge pump “VCP1”.

First, the case where the first positive voltage output from the first charge pump “VCP1” is monitored will be described.

As shown in FIG. 6, at a time “t1”, the controlling circuit “CON” sets the controlling signals “SA” and “SQ1” to “SQ3” at a “High” level and the controlling signals “SP1” to “SP4” and “SR” at a “Low” level. The controlling signals “SB” and “SC” (not shown) are maintained at the “Low” level. In this embodiment, each switch is turned on when the controlling signal is at the “High” level and turned off when the controlling signal is at the “Low” level.

As a result, as shown in FIG. 2, the first positive-side switch “SW1a” and the first negative-side switch “SW1b” are turned on, and the second positive-side switch “SW2a”, the third positive-side switch “SWNa”, the second negative-side switch “SW2b” and the third negative-side switch “SWNb” are turned off.

Furthermore, the first to fourth upper switches “1a” to “4a” and the first to fourth lower switches “1b” to “4b” are turned off, and the first to third connection switches “1x” to “3x” are turned on.

As a result, between the first detection node “ND1” and the second detection node “ND2”, the first connection state occurs where all of the plurality of monitoring capacitors “C1”, “C2”, “C3” and “C4” are electrically connected in series with each other (see FIG. 2).

In summary, the controlling circuit “CON” turns on the first positive-side switch “SW1a” and the first negative-side switch “SW1b”, turns off the second positive-side switch “SW2a”, the third positive-side switch “SWNa”, the second negative-side switch “SW2b” and the third negative-side switch “SWNb”, and sets the switch circuit “SWC” in the first connection state.

As a result, the voltage of the first smoothing capacitor “CH1” (the first positive voltage) and the voltage of the first to fourth monitoring capacitors “C1” to “C4” connected in series with each other equal to each other.

After that, as shown in FIG. 6, the controlling circuit “CON” sets the controlling signals “SA” and “SQ1” to “SQ3” at the “Low” level.

That is, the controlling circuit “CON” turns off the first to third positive-side switches “SW1a” to “SWNa” and the first to third negative-side switches “SW1b” to “SWNb”, and the first to third connection switches “1x” to “3x” are turned off.

As a result, the first to fourth monitoring capacitors “C1” to “C4” are separated from each other.

After that, as shown in FIG. 6, at a time “t2”, the controlling circuit “CON” sets the controlling signals “SP1” to “SP4” at the “High” level.

That is, the controlling circuit “CON” turns on the first to fourth upper switches “1a” to “4a” and the first to fourth lower switches “1b” to “4b”.

As a result, between the first output node “Na” and the second output node “Nb”, the second connection state occurs where all of the plurality of monitoring capacitors “C1” to “C4” are electrically connected in parallel with each other (see FIG. 3).

After that, as shown in FIG. 6, at a time “t3”, the controlling circuit “CON” sets the controlling signal “SR” at the “High” level. At the same time, the voltage of each monitoring capacitor becomes “Vhold”.

As a result, the reset switch “SWX” is turned on, and the output capacitor “CX” is discharged (see FIG. 4).

Furthermore, the controlling circuit “CON” sets the enable signal “EN” at the “High” level. As a result, the comparator “COMP” starts being driven.

As a result, the comparator “COMP” outputs the comparison result signal “COUT” that is based on the result of comparison between the signal (the voltage “Vhold”) at the first output node “Na” and the signal (a voltage “VX”) at the reference node “NX”. Since the voltage “Vhold” is equal to or higher than the voltage “VX”, the comparison result signal “COUT” is at the “Low” level.

As described above, the controlling circuit “CON” brings the switch circuit “SWC” into the second connection state and then turns on the reset switch “SWX” and drives the comparator “COMP” with the enable signal “EN”.

After that, as shown in FIG. 6, at a time “t4”, the controlling circuit “CON” sets the controlling signal “SR” at the “Low” level.

As a result, the reset switch “SWX” is turned off, and the constant current source “Iref” starts charging the output capacitor “CX” with a constant current (see FIG. 5).

After that, as shown in FIG. 6, at a time “t5”, when the voltage “Vhold” becomes lower than the voltage “VX”, the comparator “COMP” sets the comparison result signal “COUT” at the “High” level (that is, inverts the logic). That is, if the magnitude relationship between the voltage “Vhold” and the voltage “VX” is inverted, the output comparison result signal “COUT” is set at the “High” level.

After that, as shown in FIG. 6, at a time “t6”, the controlling circuit “CON” sets the controlling signal “SR” at the “High” level.

As a result, the reset switch “SWX” is turned on, and the output capacitor “CX” is discharged (see FIG. 4).

After that, as shown in FIG. 6, at a time “t7”, the controlling circuit “CON” sets the controlling signal “SR” at the “Low” level.

As a result, the reset switch “SWX” is turned off, and the constant current source “Iref” starts charging the output capacitor “CX” with a constant current (see FIG. 5).

After that, as shown in FIG. 6, at a time “t8”, when the voltage “Vhold” becomes lower than the voltage “VX”, the comparator “COMP” sets the comparison result signal “COUT” at the “High” level (that is, inverts the logic).

After that, the same operation is repeated.

As described above, the level shift circuit “LC” shapes the waveform of, and shifts the signal level of, the comparison result signal “COUT” and outputs the resulting signal to the pad electrode “PAD” as the monitoring signal “SOUT”.

That is, the output circuit 101 outputs the monitoring signal “SOUT” based on the potential difference between the first output node “Na” and the second output node “Nb” at the time when the switch circuit “SWC” is in the second connection state.

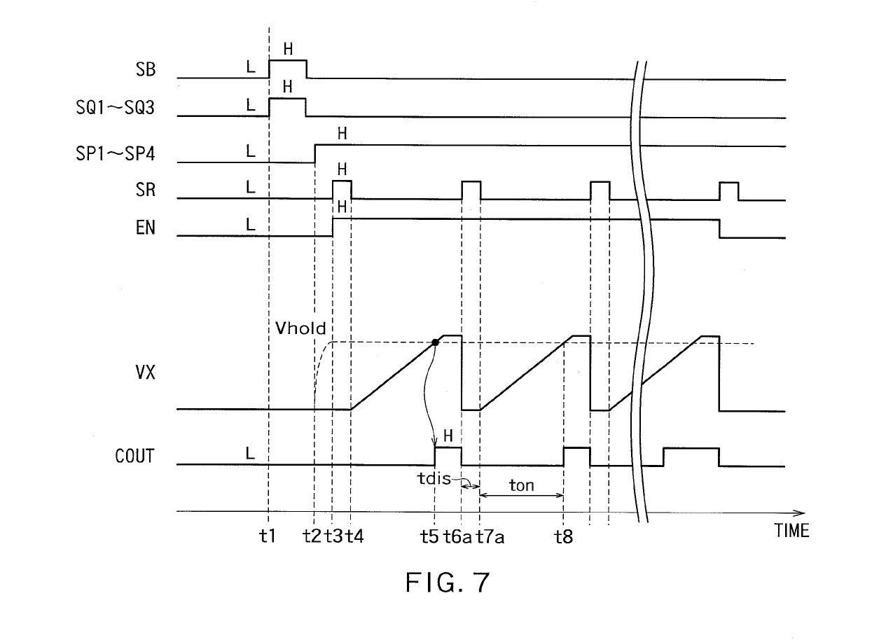

A case where the second positive voltage output from the second charge pump “VCP2” can be described in the same way as in the case where the first positive voltage is monitored. FIG. 7 is a waveform diagram showing an example of signal waveforms in the voltage monitoring circuit 100 in the case where the second positive voltage output from the second charge pump “VCP2” is monitored.

As shown in FIG. 7, at a time “t1”, the controlling circuit “CON” sets the controlling signals “SB” and “SQ1” to “SQ3” at the “High” level and the controlling signals “SP1” to “SP4” and “SR” at the “Low” level. The controlling signals “SA” and “SC” (not shown) are maintained at the “Low” level.

As a result, the second positive-side switch “SW2a” and the second negative-side switch “SW2b” are turned on, and the first positive-side switch “SW1a”, the third positive-side switch “SWNa”, the first negative-side switch “SW1b” and the third negative-side switch “SWNb” are turned off.

Furthermore, the first to fourth upper switches “1a” to “4a” and the first to fourth lower switches “1b” to “4b” are turned off, and the first to third connection switches “1x” to “3x” are turned on.

As a result, between the first detection node “ND1” and the second detection node “ND2”, the first connection state occurs where all of the plurality of monitoring capacitors “C1”, “C2”, “C3” and “C4” are electrically connected in series with each other.

In summary, the controlling circuit “CON” turns on the second positive-side switch “SW2a” and the second negative-side switch “SW2b”, turns off the first positive-side switch “SW1a”, the third positive-side switch “SWNa”, the first negative-side switch “SW1b” and the third negative-side switch “SWNb”, and sets the switch circuit “SWC” in the first connection state.

As a result, the voltage of the second smoothing capacitor “CH2” (the second positive voltage) and the voltage of the first to fourth monitoring capacitors “C1” to “C4” connected in series with each other equal to each other.

To the following part of the process, the above description with regard to FIG. 6 applies.

A case where the negative voltage output from the third charge pump “VNCP” can be described in the same way as the cases where the first and second positive voltages are monitored.

That is, in the case where the negative voltage output from the third charge pump “VNCP” is monitored, the controlling circuit “CON” turns on the third positive-side switch “SWNa” and the third negative-side switch “SWNb”, turns off the first positive-side switch “SW1a”, the second positive-side switch “SW2a”, the first negative-side switch “SW2a” and the second negative-side switch “SW2b”, and sets the switch circuit “SWC” in the first connection state.

After that, the controlling circuit “CON” turns off the third positive-side switch “SWNa” and the third negative-side switch “SWNb”.

After that, as in the cases where the first and second positive voltages are monitored, the controlling circuit “CON” brings the switch circuit “SWC” into the second connection state.

As in the cases where the first and second positive voltages are monitored, the output circuit 101 then outputs the monitoring signal “SOUT” based on the potential difference between the first output node “Na” and the second output node “Nb” at the time when the switch circuit “SWC” is in the second connection state.

Next, an example of a method of calculating an internal voltage (the first positive voltage in this example) from the monitoring signal “SOUT” will be described.

In this example, as described below, the internal voltage to be determined is determined by measuring a time from a point in time when the reset switch “SWX” in the on state is turned off to a point in time when the output of the comparator “COMP” is inverted.

A charge “Q” in a capacitor “C” is expressed by the following formula (1). In the formula (1), “V” denotes a voltage of the capacitor “C”, an “i” denotes a current supplied to the capacitor “C”.

Q=CV=∫idt (1)

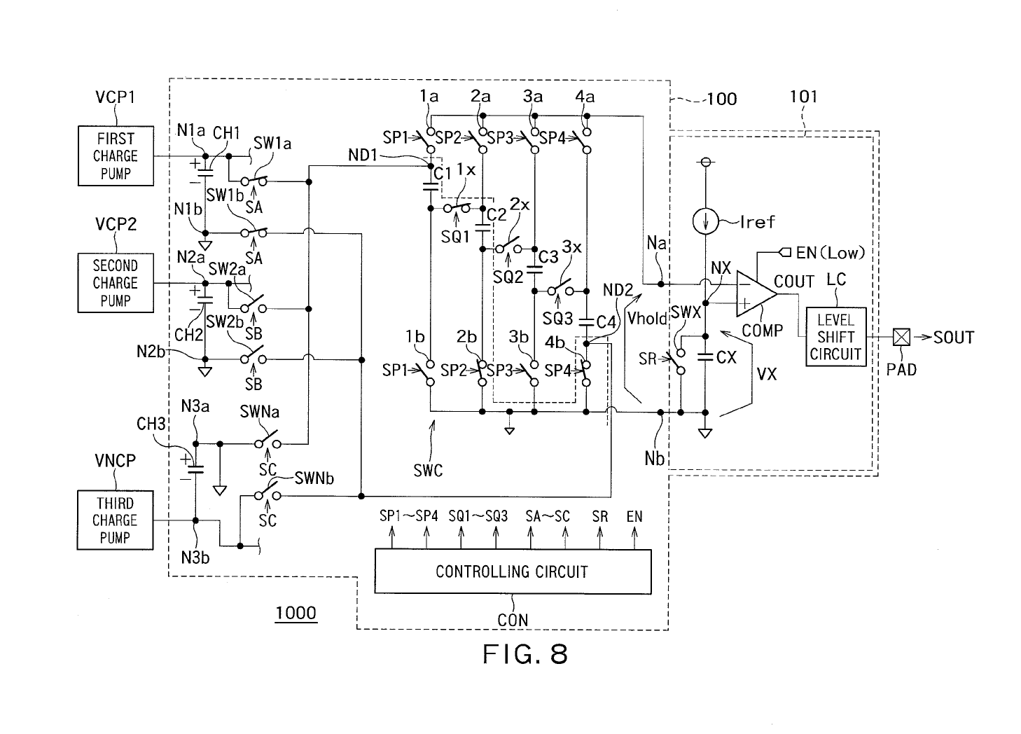

From the formula (1), a voltage “Vmeas”, which is a measurement of the first positive voltage, is expressed by the formula (2). In the formula (2), “Iref” denotes a constant current output from the constant current source (“Iref”), and “ton” denotes a period from a point in time when the reset switch “SWX” is turned off to a point in time when the output of the comparator “COMP” is inverted (from the time “t7” to the time “t8” in FIG. 8).

Vmeas=(Iref/Ctotal)*ton (2)

Ctotal=1/(1/C1+1/C2+ . . . +1/Cn) (N=4, in the example shown in FIG. 1)

For example, suppose that Iref=1 μA, C1=C2=C3= . . . =Cn=1 pF, and Ton=2 μsec. In this case, the voltage “Vmeas” is calculated as the formula (3) according to the formula (2).

$$Vmeas = ( Iref / Ctotal ) * Ton = ( 1 uA / ( 1 / n * 1 pF ) ) * 2 usec \qquad ( 3 )$$

The measured voltage Vmeas is determined to be 8 V by substituting 4 for n in the formula (3).

The period for which the comparison result signal “COUT” is at the “Low” level is divided into a period “tdis” and a period “ton” (see FIG. 6). The period “tdis” is the period for which the reset switch “SWX” is in the on state, and the length of the period is a known value. Therefore, the period “ton” can be determined by subtracting the period “tdis” from the period for which the comparison result signal “COUT” is at the “Low” level.

As described above, the output circuit 101 outputs the comparison result signal “COUT” (the monitoring signal “SOUT”) based on the potential difference between the first output node “Na” and the second output node “Nb” at the time when the switch circuit “SWC” is in the second connection state. The voltage “Vmeas” as the first positive voltage can be determined by monitoring the comparison result signal “COUT” (the monitoring signal “SOUT”).

As described above, the voltage monitoring circuit according to the first embodiment converts each boosted analog voltage into a voltage that falls within a certain voltage range by once accumulating charge in divisional capacitors in a series connection and then rearranging the capacitors into a parallel connection.

Furthermore, constant current charging is performed with the constant current source “Iref” and the monitoring capacitors “C1” to “C4”, and the comparator “COMP” compares the internal voltage with a time proportional voltage, thereby measuring the internal voltage by calculation based on the information on the internal constant current, the capacitances and the inversion period of the comparator “COMP”.

The internal voltage is equivalently measured by repeating these operations to read the duty cycle of the output of the comparator “COMP”.

As a result, the pad electrode “PAD” can be used in combination with another digital I/O terminal. Thus, no dedicated pad is required, and the internal analog voltage can be monitored on the product package by reading the analog voltage in the form of a digital output converted from the analog voltage.

In addition, since the number of monitoring capacitors connected in series with each other can be adjusted, even a high output voltage to be measured can be reduced to fall within a determination voltage range of the comparator “COMP” when the monitoring capacitors are connected in parallel with each other.

(Modification)

In the first connection state described above, for example, any of the plurality of monitoring capacitors “C1”, “C2”, “C3” and “C4” may be electrically connected in series with each other between the first detection node “ND1” and the second detection node “ND2”. In the second connection state, any of the plurality of monitoring capacitors “C1”, “C2”, “C3” and “C4” may be electrically connected in parallel with each other between the first output node “Na” and the second output node “Nb”.

This results in a reduction of the capacitance of the monitoring capacitors to be charged or discharged, so that the voltage “Vhold” can be set within the effective range of the input voltage of the comparator “COMP” to provide for a low input power supply.

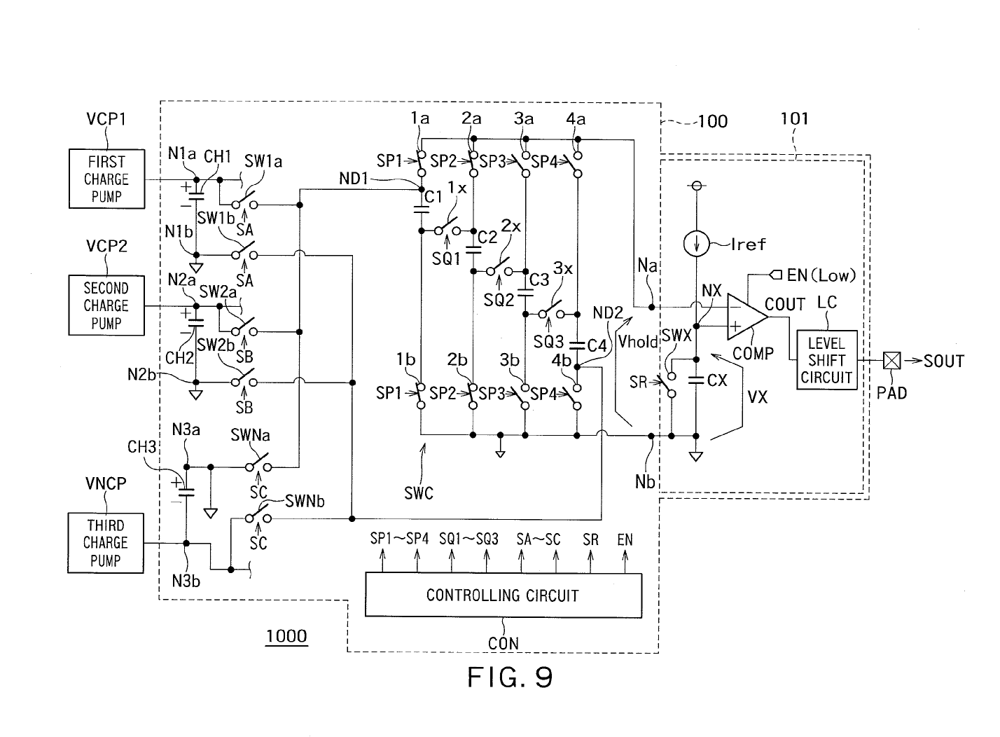

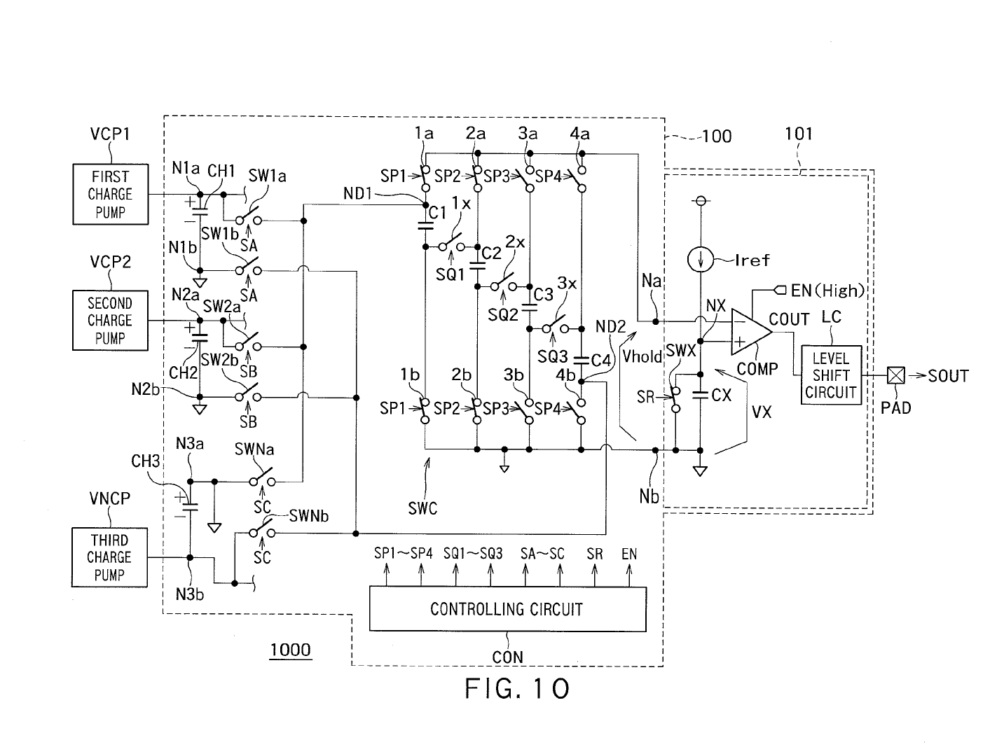

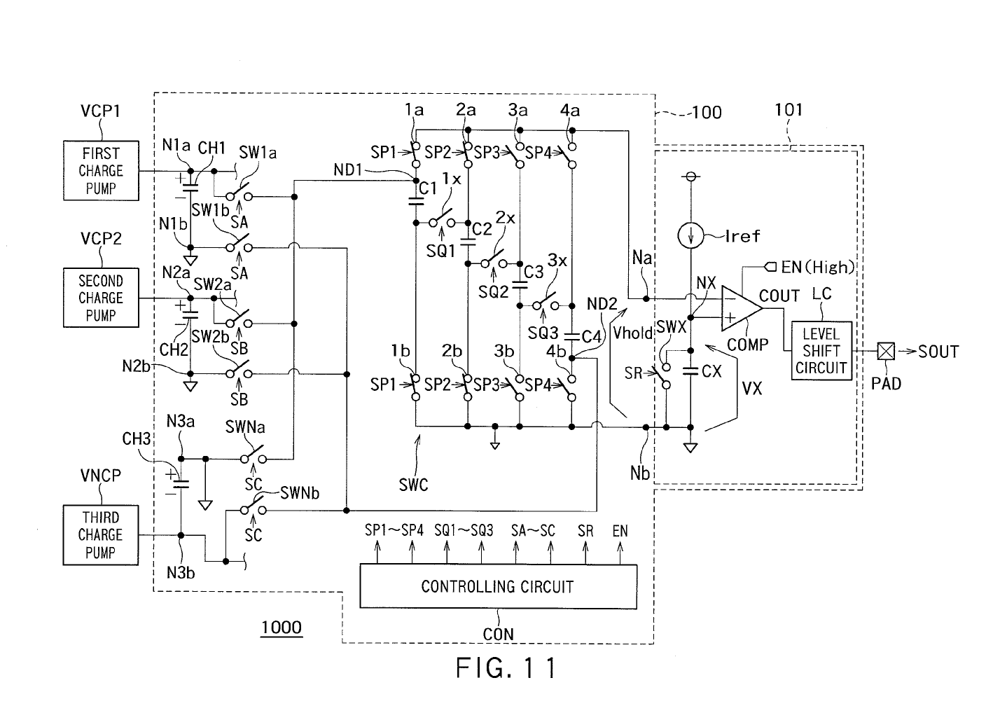

FIG. 8 is a diagram showing another example of the interconnections in the semiconductor integrated circuit 1000 in the case where the switch circuit “SWC” in FIG. 1 is in the first connection state. FIG. 9 is a diagram showing another example of the state where the switch circuit “SWC” in FIG. 1 is in the second connection state. FIG. 10 is a diagram showing another example of the state where the reset switch “SWX” in the output circuit 101 is turned on after the switch circuit “SWC” in the voltage monitoring circuit 100 is once in the first connection state. FIG. 11 is a diagram showing another example of the state where the output circuit 101 in FIG. 1 outputs the monitoring signal “SOUT” responsive to the potential difference between the first output node “Na” and the second output node “Nb”.

In the first connection state described above, for example, only two of the plurality of monitoring capacitors “C1”, “C2”, “C3” and “C4”, such as the first monitoring capacitor “C1” and the second monitoring capacitor “C2”, may be electrically connected in series with each other between the first detection node “ND1” and the second detection node “ND2” (see FIG. 8).

In this case, in the second connection state, only two monitoring capacitors “C1” and “C2” are electrically connected in parallel with each other between the first output node “Na” and the second output node “Nb” (see FIG. 9).

The reset switch “SWX” is then turned on to discharge the output capacitor “CX” (see FIG. 10), and the reset switch “SWX” is turned off to make the constant current source “Iref” start charging the output capacitor “CX” with a constant current.

The remainder of the operation is the same as that of the voltage monitoring circuit described with reference to FIGS. 4 to 7.

In this case, the monitoring capacitors to be charged or discharged are the first monitoring capacitor “C1” and the second monitoring capacitor “C2”, and the capacitance to be charged or discharged is reduced, so that the voltage “Vhold” can be set within the effective range of the input voltage of the comparator “COMP” to provide for a low input power supply.

As described above, the voltage monitoring circuit according to the first embodiment can measure the internal voltage with a reduced number of pads.

As an alternative, the output of each charge pump may be trimmed based on the comparison result signal “COUT” (or the monitoring signal “SOUT”) obtained by the voltage monitoring circuit monitoring the output of each charge pump.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A voltage monitoring circuit that outputs a monitor signal, the voltage monitoring circuit comprising:
a first smoothing capacitor connected between a first positive-side node and a first negative-side node;
a first positive-side switch connected between a first detection node and the first positive-side node;
a first negative-side switch connected between a second detection node and the first negative-side node;
a plurality of monitoring capacitors disposed the first detection node and the second detection node;
a switch circuit being capable of switching between a first connection state and a second connection state, and in the first connection state, the monitoring capacitors being electrically connected in series with each other between the first detection node and the second detection node, and in the second connection state, the monitoring capacitors being electrically connected in parallel with each other between a first output node and a second output node;
an output circuit that outputs the monitoring signal according to the potential difference between the first output node and the second output node; and
a controlling circuit that controls the first positive-side switch, the first negative-side switch and the switch circuit.

2. The voltage monitoring circuit, according to claim 1,
wherein the controlling circuit turns on the first positive-side switch and the first negative-side switch, and sets the switch circuit in the first connection state, and
after that, the controlling circuit turns off the first positive-side switch and the first negative-side switch, and
after that, the controlling circuit sets the switch circuit in the second connection state, and
the output circuit outputs the monitoring signal based on the potential difference between the first output node and the second output node at the time when the switch circuit is in the second connection state.

3. The voltage monitoring circuit, according to claim 1,
wherein, in the first connection state, at least two of the plurality of monitoring capacitors are electrically connected in series with each other between the first detection node and the second detection node, and
wherein, in the second connection state, the monitoring capacitors connected in series with each other in the first connection state are electrically connected in parallel with each other between the first output node and the second output node.

4. The voltage monitoring circuit, according to claim 1, further comprising:
a second smoothing capacitor connected between a second positive-side node and a second negative-side node;
a second positive-side switch connected between the first detection node and the second positive-side node; and
a second negative-side switch connected between the second detection node and the second negative-side node, and
wherein the controlling circuit turns off the first positive-side switch and the first negative-side switch and turns on the second positive-side switch and the second negative-side switch and sets the switch circuit in the first connection state, and
after that, the controlling circuit turns off the second positive-side switch and the second negative-side switch, and
after that, the controlling circuit sets the switch circuit in the second connection state, and
the output circuit outputs the monitoring signal based on the potential difference between the first output node and the second output node at the time when the switch circuit is in the second connection state.

5. The voltage monitoring circuit, according to claim 1, further comprising:
a third smoothing capacitor connected between a third positive-side node and a third negative-side node;
a third positive-side switch connected between the first detection node and the third positive-side node; and
a third negative-side switch connected between the second detection node and the third negative-side node.

6. The voltage monitoring circuit, according to claim 5,
wherein, the controlling circuit turns on the third positive-side switch and the third negative-side switch, and turns off the first positive-side switch, the second positive-side switch, the first negative-side switch and the second negative-side switch, and sets the switch circuit in the first connection state, and
after that, the controlling circuit turns off the third positive-side switch and the third negative-side switch, and
after that, the controlling circuit sets the switch circuit in the second connection state, and
the output circuit outputs the monitoring signal based on the potential difference between the first output node and the second output node at the time when the switch circuit is in the second connection state.

7. The voltage monitoring circuit, according to claim 1,
wherein the output circuit comprises:
a constant current source connected to a power supply at a first end thereof and to a reference node at a second end thereof and outputs a constant current;
an output capacitor connected to the reference node at a first end thereof and to the second output node and a fixed potential at a second end thereof;
a reset switch connected in parallel with the output capacitor between the reference node and the second output node, the reset switch controlled by the controlling circuit; and
a comparator outputs a comparison result signal that is based on the result of comparison between a signal at the first output node and a signal at the reference node, and
wherein the output circuit outputs the monitoring signal responsive to the comparison result signal.

8. The voltage monitoring circuit, according to claim 7,
wherein the comparator is driven in response to an enable signal, and
the controlling circuit brings the switch circuit into the second connection state and then turns on the reset switch and drives the comparator with the enable signal, and
after that, the controlling circuit turns off the reset switch, and
after that, the controlling circuit measures a time that takes until a magnitude relationship of a potential between the signal at the reference node and the signal at the output node is inverted.

9. The voltage monitoring circuit, according to claim 2,
wherein the output circuit comprises:
a constant current source connected to a power supply at a first end thereof and to a reference node at a second end thereof and outputs a constant current;
an output capacitor connected to the reference node at a first end thereof and to the second output node and a fixed potential at a second end thereof;
a reset switch connected in parallel with the output capacitor between the reference node and the second output node, the reset switch controlled by the controlling circuit; and
a comparator outputs a comparison result signal that is based on the result of comparison between a signal at the first output node and a signal at the reference node, and
wherein the output circuit outputs the monitoring signal responsive to the comparison result signal.

10. The voltage monitoring circuit, according to claim 9,
wherein the comparator is driven in response to an enable signal, and
the controlling circuit brings the switch circuit into the second connection state and then turns on the reset switch and drives the comparator with the enable signal, and
after that, the controlling circuit turns off the reset switch, and
after that, the controlling circuit measures a time that takes until a magnitude relationship of a potential between the signal at the reference node and the signal at the output node is inverted.

11. A semiconductor integrated circuit, comprising a first charge pump and a voltage monitoring circuit, and the first charge pump connected to a first positive-side node at an output, and the first charge pump outputs a first positive voltage, and the voltage monitoring circuit monitors voltage and outputs a monitor signal that is based on the result of the monitoring, and the voltage monitoring circuit comprising:
a first smoothing capacitor connected between a first positive-side node and a first negative-side node, and the first positive-side node being supplied to the first positive voltage, and the first negative-side node connected to a fixed potential;
a first positive-side switch connected between a first detection node and the first positive-side node;
a first negative-side switch connected between a second detection node and the first negative-side node;
a plurality of monitoring capacitors disposed the first detection node and the second detection node;
a switch circuit being capable of switching between a first connection state and a second connection state, and in the first connection state, the monitoring capacitors being electrically connected in series with each other between the first detection node and the second detection node, and in the second connection state, the monitoring capacitors being electrically connected in parallel with each other between the first output node and the second output node;
an output circuit that outputs the monitoring signal according to the potential difference between the first output node and the second output node; and
a controlling circuit that controls the first positive-side switch, the first negative-side switch and the switch circuit.

12. The semiconductor integrated circuit, according to claim 11,
wherein the controlling circuit turns on the first positive-side switch and the first negative-side switch, and sets the switch circuit in the first connection state, and
after that, the controlling circuit turns off the first positive-side switch and the first negative-side switch, and
after that, the controlling circuit sets the switch circuit in the second connection state, and
the output circuit outputs the monitoring signal based on the potential difference between the first output node and the second output node at the time when the switch circuit is in the second connection state.

13. The semiconductor integrated circuit, according to claim 11,
wherein, in the first connection state, at least two of the plurality of monitoring capacitors are electrically connected in series with each other between the first detection node and the second detection node, and
wherein, in the second connection state, the monitoring capacitors connected in series with each other in the first connection state are electrically connected in parallel with each other between the first output node and the second output node.

14. The semiconductor integrated circuit, according to claim 11, further comprising:
a second charge pump connected to a second positive-side node at an output, and the second charge pump outputs a second positive voltage;
a second smoothing capacitor connected between a second positive-side node and a second negative-side node, and the second positive-side node being supplied to the second positive voltage, and the second negative-side node connected to the fixed potential;
a second positive-side switch connected between the first detection node and the second positive-side node; and
a second negative-side switch connected between the second detection node and the second negative-side node, and
wherein the controlling circuit turns off the first positive-side switch and the first negative-side switch and turns on the second positive-side switch and the second negative-side switch and sets the switch circuit in the first connection state,
after that, the controlling circuit turns off the second positive-side switch and the second negative-side switch,
after that, the controlling circuit sets the switch circuit in the second connection state, and
the output circuit outputs the monitoring signal based on the potential difference between the first output node and the second output node at the time when the switch circuit is in the second connection state.

15. The semiconductor integrated circuit, according to claim 11, further comprising:
a third charge pump connected to a third negative-side node at an output, and the third charge pump outputs a negative voltage;
a third smoothing capacitor connected between a third positive-side node, which is connected to the fixed potential, and a third negative-side node, to which the negative voltage is supplied;
a third positive-side switch connected between the first detection node and the third positive-side node; and
a third negative-side switch connected between the second detection node and the third negative-side node.

16. The semiconductor integrated circuit, according to claim 15,
wherein, the controlling circuit turns on the third positive-side switch and the third negative-side switch, and turns off the first positive-side switch, the second positive-side switch, the first negative-side switch and the second negative-side switch, and sets the switch circuit in the first connection state, and
after that, the controlling circuit turns off the third positive-side switch and the third negative-side switch, and
after that, the controlling circuit sets the switch circuit in the second connection state, and
the output circuit outputs the monitoring signal based on the potential difference between the first output node and the second output node at the time when the switch circuit is in the second connection state.

17. The semiconductor integrated circuit, according to claim 11,
wherein the output circuit comprises:
a constant current source connected to a power supply at a first end thereof and to a reference node at a second end thereof and outputs a constant current;
an output capacitor connected to the reference node at a first end thereof and to the second output node and the fixed potential at a second end thereof;
a reset switch connected in parallel with the output capacitor between the reference node and the second output node, the reset switch controlled by the controlling circuit; and
a comparator outputs a comparison result signal that is based on the result of comparison between a signal at the first output node and a signal at the reference node, and
wherein the output circuit outputs the monitoring signal responsive to the comparison result signal.

18. The semiconductor integrated circuit, according to claim 17,
wherein the comparator is driven in response to an enable signal, and
the controlling circuit brings the switch circuit into the second connection state and then turns on the reset switch and drives the comparator with the enable signal, and
after that, the controlling circuit turns off the reset switch, and
after that, the controlling circuit measures a time that takes until a magnitude relationship of a potential between the signal at the reference node and the signal at the output node is inverted.

19. The semiconductor integrated circuit, according to claim 12,
wherein the output circuit comprises:
a constant current source connected to a power supply at a first end thereof and to a reference node at a second end thereof and outputs a constant current;
an output capacitor connected to the reference node at a first end thereof and to the second output node and the fixed potential at a second end thereof;
a reset switch connected in parallel with the output capacitor between the reference node and the second output node, the reset switch controlled by the controlling circuit; and
a comparator outputs a comparison result signal that is based on the result of comparison between a signal at the first output node and a signal at the reference node, and
wherein the output circuit outputs the monitoring signal responsive to the comparison result signal.

20. The semiconductor integrated circuit, according to claim 19,
wherein the comparator is driven in response to an enable signal, and
the controlling circuit brings the switch circuit into the second connection state and then turns on the reset switch and drives the comparator with the enable signal, and
after that, the controlling circuit turns off the reset switch, and
after that, the controlling circuit measures a time that takes until a magnitude relationship of a potential between the signal at the reference node and the signal at the output node is inverted.
